(19) United States
(12) Patent Application Publication
(10) Pub. No.: US 2026/0081586 A1
(43) Pub. Date: Mar. 19, 2026

(54) COMPARATOR WITH MODULABLE REFERENCE AND REFERENCE OBSERVABILITY SUPPORT

(71) Applicant: Cypress Semiconductor Corporation, San Jose, CA (US)

(72) Inventors: Nandakishore RAIMAR, Bangalore (IN); Brajveer SINGH, Bangaluru (IN)

(73) Assignee: Cypress Semiconductor Corporation, San Jose, CA (US)

(21) Appl. No.: 18/889,116

(22) Filed: Sep. 18, 2024

(51) Int. Cl. H03K 5/24; H03M 1/66

(52) U.S. Cl. CPC H03K 5/249; H03M 1/66

(57) ABSTRACT

A comparator circuit includes a matching capacitor in series with a first switching device and a second switching device. The first and second switching devices are in parallel between the matching capacitor and a reference voltage. The comparator circuit further includes a sampling capacitor in series with a third switching device and a fourth switching device. The third switching device is in series between the sampling capacitor and a DAC, and the fourth switching device is in series between the sampling capacitor an input voltage. The comparator circuit further includes a comparator having an inverting input terminal and a non-inverting input terminal. The inverting input terminal is capacitively coupled to the matching capacitor and the non-inverting input terminal is capacitively coupled to the sampling capacitor. The comparator circuit further includes a fifth switching device and a sixth switching device in series between the matching capacitor and the sampling capacitor.

### FIELD OF THE INVENTION

Embodiments of the present disclosure relate generally to comparators in electronic circuits. More specifically, embodiments of the present disclosure relate to a high-speed auto-zero comparator with modulable reference and reference observability support.

### BACKGROUND

A comparator is a device that is widely used in electronic circuits. It generally compares two voltages or currents and outputs a digital signal indicating which is larger. A comparator generally includes a specialized high-gain differential amplifier, and it is commonly used in devices that measure and digitize analog signals, such as analog-to-digital converters (ADCs), as well as relaxation oscillators.

In certain applications (e.g., automotive, industrial, microcontroller, programmable system on a chip (PSoC), etc.), a high bandwidth voltage to pulse-width modulation (PWM) transfer function is required to support certain switch loop implementations. These applications also require a precision event detection mechanism (e.g., overvoltage or overcurrent) to achieve fast fault and accurate detection.

To address those requirements, a precision comparator with a modulable reference (e.g., by way of digital-to-analog converter (DAC) controls), such as a high-speed auto-zero comparator circuit 100 with dedicated auto-zero phase illustrated in FIG. 1, can be used.

As shown in FIG. 1, comparator circuit 100 includes a comparator 102 connected to input terminals 121-122 (e.g., inverting and non-inverting terminals), which are capacitively coupled to matching capacitor 101 and sampling capacitor 111 of comparator circuit 100. Comparator 102 provides complementary output signals at output terminal 123 by comparing input signals applied to the input terminals 121-122. Matching capacitor 101 (also referred to as a dummy capacitor) and sampling capacitor 111 can have the same capacitance value. As further shown in FIG. 1, comparator circuit 100 further includes switches 103-104 connected in series between matching capacitor 101 and sampling capacitor 111, with the matching capacitor 101 connecting between ground (GND) and switch 103. Input terminal 121 is also connected to a node between matching capacitor 101 and switch 103, and input terminal 122 is also connected to a node between switch 104 and sampling capacitor 111. A common mode voltage (VCM) is connected to a node between switch 103 and switch 104.

Furthermore, comparator circuit 100 also includes a switch 105 connected between input voltage VIN and sampling capacitor 111, and switches 106-107 connected in series between GND and a node between switch 105 and sampling capacitor 111. Comparator circuit 100 further includes a capacitive digital-to-analog converter (CAP DAC) 120 connected to a node between sampling capacitor 111 and input terminal 122. As shown, CAPDAC 120 includes a capacitor (or capacitor array) 112 and array of switches 108-110. Switch 108 is connected in series with capacitor array 112 between GND or reference voltage high (VREFH) and the node between sampling capacitor 111 and input terminal 122. Switches 109-110 are connected in parallel between VREFH and a node between capacitor 112 and switch 108 to form a capacitive DAC.

During auto-zero phase, switches 103, 104, 106, 107, 110 are closed and rest are open. During sampling phase, switches 103, 105, 110 are closed. During resolve phase, switches 106, 107 are closed and DAC switch array (108, 109) is configured to inject a reference voltage in the form of a charge, which results in a voltage at switch 104 to get resolved by comparator 102 at its output terminal 123.

Unfortunately, in the architecture of comparator circuit 100, VREFH is not observable, gain error exists due to the mismatch between the sampling capacitor 111 and the CAP DAC 120, the used sampling capacitor grows larger to contain gain error (which results in a slower DAC transition), and a larger sampling capacitor would correspond to a lower input impedance. Furthermore, with the architecture of the comparator circuit 100, a periodic dedicated auto-zero phase is required, thereby resulting in a periodic blind zone to contain the offset voltage of the comparator 102.

### BRIEF DESCRIPTION OF THE DRAWINGS

Embodiments of the disclosure are illustrated by way of example and not limitation in the figures of the accompanying drawings in which like references indicate similar elements.

FIG. 1 is a schematic diagram of a conventional auto-zero comparator circuit with a modulable reference using a capacitive DAC.

FIG. 2 is a schematic diagram of an incremental auto-zero comparator circuit according to an embodiment.

FIG. 3A is a schematic diagram illustrating an incremental auto-zero high-speed comparator circuit operating in a sample phase according to an embodiment.

FIG. 3B is a schematic diagram illustrating the incremental auto-zero high-speed comparator circuit of FIG. 3A operating in a resolve phase according to an embodiment.

FIG. 3C is a timing diagram illustrating a clock signal and comparator output signals associated with the comparator circuit of FIGS. 3A-3B.

FIG. 4 is a schematic diagram illustrating an incremental auto-zero high-speed comparator circuit with DAC as reference according to an embodiment.

FIG. 5A is a schematic diagram illustrating an incremental auto-zero high-speed comparator circuit with reference voltage observability according to an embodiment.

FIG. 5B is a timing diagram illustrating signals associated with the comparator circuit of FIG. 5A with a windowing phase controlling a switch for reference observability.

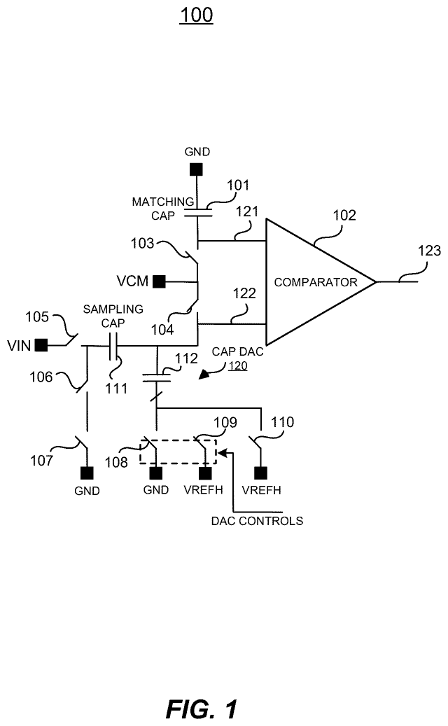

### DETAILED DESCRIPTION

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

According to one aspect, a comparator circuit may include a matching capacitor in series with a first switching device and a second switching device. The first and second switching devices may be in parallel between the matching capacitor and a reference voltage. The comparator circuit may further include a sampling capacitor in series with a third switching device and a fourth switching device. The third switching device may be in series between the sampling capacitor and a DAC, and the fourth switching device may be in series between the sampling capacitor and an input voltage. The comparator circuit may further include a comparator having an inverting input terminal and a non-inverting input terminal. The inverting input terminal may be capacitively coupled to the matching capacitor and the non-inverting input terminal may be capacitively coupled to the sampling capacitor. The comparator circuit may further include a fifth switching device and a sixth switching device in series between the matching capacitor and the sampling capacitor.

According to another aspect, a comparator circuit may include a number of cascaded comparator amplifiers. The comparator circuit may further include a matching capacitor in series with a first switching device and a second switching device. The first and second switching devices may be in parallel between the matching capacitor and a common mode voltage. The comparator circuit may further include a sampling capacitor in series with a third switching device and a fourth switching device. The third switching device may be in series between the sampling capacitor and an input voltage, and the fourth switching device may be in series between the sampling capacitor and a reference voltage. In an embodiment, a first comparator among the cascaded comparator amplifiers may include an inverting input terminal and a non-inverting input terminal. The inverting input terminal may be capacitively coupled to the matching capacitor and the non-inverting input terminal may be capacitively coupled to the sampling capacitor.

According to yet another aspect, a comparator circuit may include a number of cascaded comparator amplifiers. The comparator circuit may further include a matching capacitor in series with a first switching device and a second switching device. The first and second switching devices may be in parallel between the matching capacitor and a common mode voltage. The comparator circuit may further include a sampling capacitor in series with a third switching device and a fourth switching device. The third switching device may be in series between the sampling capacitor and an input voltage, and the fourth switching device may be in series between the sampling capacitor and a DAC. In an embodiment, a first comparator among the cascaded comparator amplifiers may include an inverting input terminal and a non-inverting input terminal. The inverting input terminal may be capacitively coupled to the matching capacitor and the non-inverting input terminal may be capacitively coupled to the sampling capacitor.

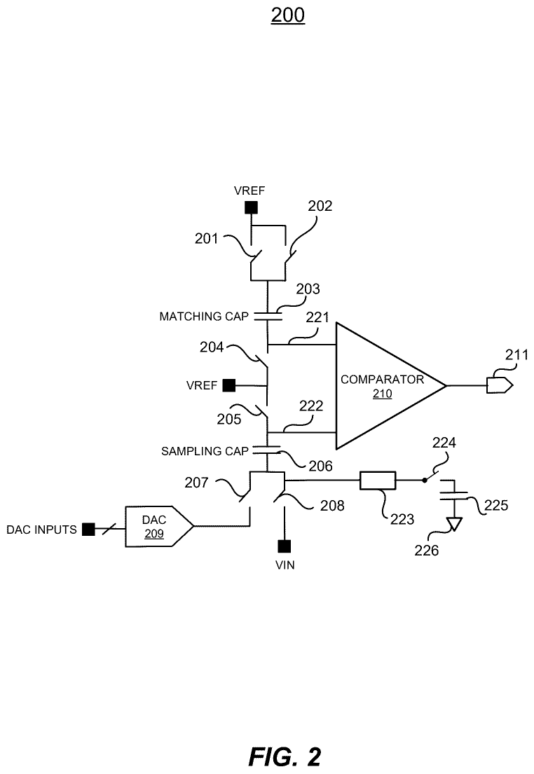

FIG. 2 is a schematic diagram of an incremental auto-zero comparator circuit according to an embodiment. Referring to FIG. 2, comparator circuit 200 may include, but not limited to, switches (or switching devices) 201-202, 204-205, 207-208 (e.g., metal-oxide-semiconductor (MOS) switches), a matching capacitor 203, a sampling capacitor 206, a voltage digital-to-analog converter (DAC) 209, and a comparator 210 (e.g., differential amplifier, such as operational amplifier (op-amp), latch comparator, etc.).

As shown, comparator 210 may be connected to input terminals 221-122 (e.g., inverting and non-inverting terminals), which may be capacitively coupled to matching capacitor 203 and sampling capacitor 206, respectively. Comparator 210 may provide complementary output signals at output terminal 211 by comparing input signals applied to the input terminals 221-222. In some embodiments, matching capacitor 203 and sampling capacitor 206 may have the same capacitance value. As further shown in FIG. 2, switches 204-205 may be connected in series between matching capacitor 203 and sampling capacitor 206. Switches 201-202 may be connected in parallel between a reference voltage (VREF) and matching capacitor 203. Switch 207 may be connected in series with DAC 209 and sampling capacitor 206, with switch 207 being in between DAC 209 and sampling capacitor 206. Switch 208 may be connected in series with input voltage (VIN) and sampling capacitor 206, with switch 208 being in between VIN and sampling capacitor 206. In the embodiment, VIN and DAC 209 along with its input bits can be swapped with each other to get a complementary comparison. In an embodiment, circuitry connected to negative input of the comparator 221 and circuitry connected to positive input of the comparator 222 may be swapped to generate the complementary function.

In an embodiment, input terminal 221 may also be connected to a node between matching capacitor 203 and switch 204, and input terminal 222 may also be connected to a node between switch 205 and sampling capacitor 206. VREF may also be connected to a node between switch 204 and switch 205.

In operation, during a first phase of a clock cycle (e.g., sampling and auto-zero phase φ1), switches 202, 204-205 and 208 can be turned on (closed) and switches 201 and 207 can be turned off (open). During a second phase of the clock cycle (e.g., resolve phase φ2), switches 202, 204-205 and 208 can be turned off (open), and switches 201 and 207 can be turned on (closed) to connect DAC 209 to sampling capacitor 206 and connect VREF to matching capacitor 201. In this scenario, sampling capacitor 206 can be used for a comparison of VIN against a DAC voltage generated by the DAC input bits configuration value.

In an embodiment, comparator circuit 200 may further include a windowed sampling mechanism of a DAC voltage that includes a resistor 223, a switch (or switching device) 224 and a DAC sampling capacitor 225 connected in series between DAC 209 (and VIN) and GND 226. In the sampling phase, switch 224 may be turned on (closed) to sample the DAC 209, using DAC sampling capacitor 225, for DAC observability. This embodiment allows the use of a separate windowing phase (φDAC) to control switch 224, which may have a delayed rising edge (phase delay) as compared to the sampling phase, when the DAC 209 is sampled. Moreover, a dedicated φDAC phase enables the incremental charging of the DAC sampling capacitor 225 when the DAC 209 is in a settle stage, thereby avoiding overshoot/undershoot error integration.

Using the architecture of comparator 200, there is no blind zone since the incremental auto-zero of the offset voltage of the comparator 210 is performed at the time of sampling the signal (e.g., VIN). Also, signal sampling (first phase) is followed by voltage superposition of DAC 209 (second phase) for comparison. In this way, there is no voltage division in the sampling voltage (thus, a smaller sampling capacitor can be used), the DAC 209 needs to charge the small parasitic capacitance of sampling capacitor 206 (which results in faster transient for relatively low power), and there is no gain error due to non-capacitor mismatch. Furthermore, with the architecture of comparator 200, windowed DAC sampling for DAC observability can be performed during operation. Thus, DAC reference is observable without transient parametric performance loss, which generally is a requirement for safety critical applications.

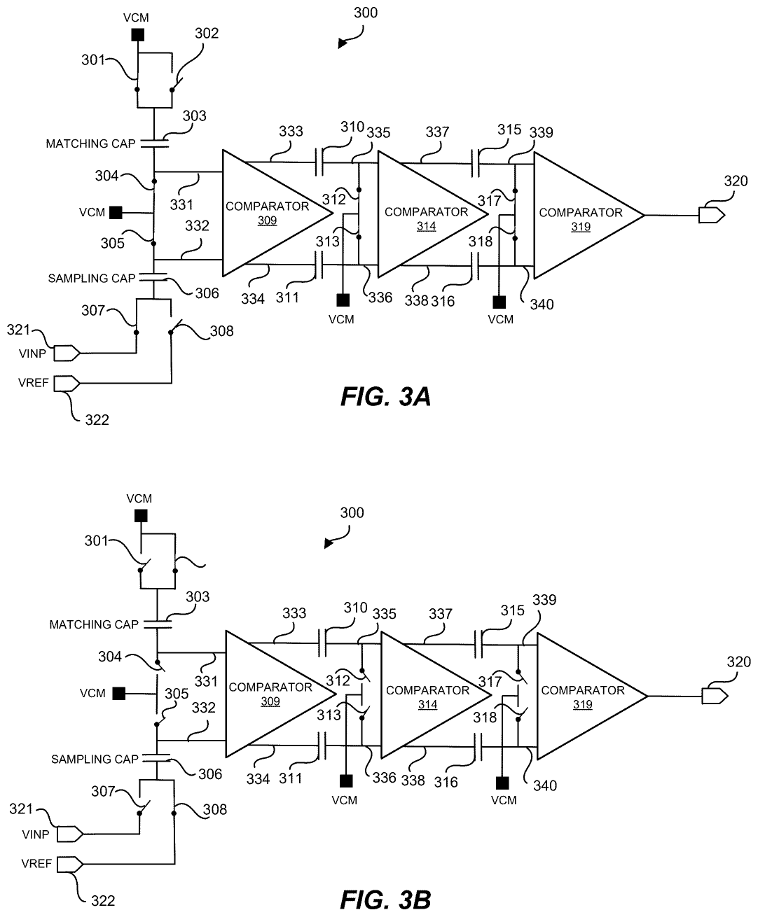

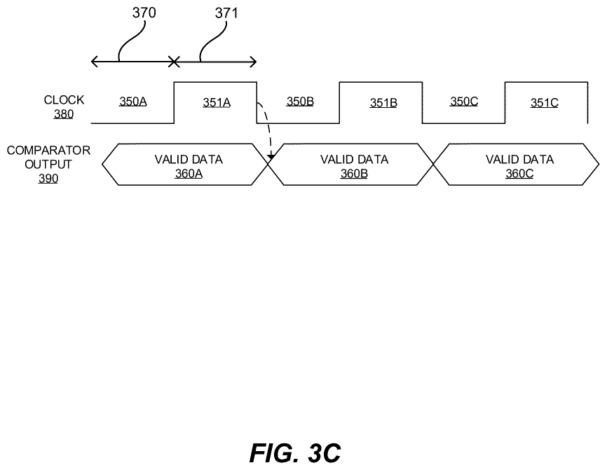

FIG. 3A is a schematic diagram illustrating an incremental auto-zero high-speed comparator circuit operating in a sample phase according to an embodiment. Referring to FIG. 3A, auto-zero high-speed comparator circuit 300 includes, but not limited to, comparators 309, 314, 319, switches (or switching devices) 301-302, 304-305, 307-308, 312-313, 317-318 (e.g., MOS switches), matching capacitor 303, sampling capacitor 306, and capacitors 310-311, 315-316.

As shown, comparators (or comparator amplifiers) 309, 314 and 319 may be connected in cascade to provide greater gain with minimal delay time. Output terminals 333-334 of comparator 309 may be capacitively coupled to input terminals 335-336 of comparator 314, respectively, via capacitors 310-311. Output terminals 337-338 of comparator 314 may be capacitively coupled to input terminals 339-340 of comparator 319, respectively, via capacitors 315-316. In some embodiments, comparators 309 and 314 may be a preamplifier (e.g., differential amplifier, such as op-amp) that amplifies the input signals applied to input terminals 331-332, and comparator 319 may be a latch comparator (e.g., strong-arm latch) that outputs complementary output signals at output terminal 320 by comparing the amplified input signals. In an embodiment, each of the terminals 333-340 may be an inverting or non-inverting terminal.

With continued reference to FIG. 3A, comparator 309 may be connected to input terminals 331-332 (e.g., inverting and non-inverting terminals), which may be capacitively coupled to matching capacitor 303 and sampling capacitor 306, respectively. In some embodiments, matching capacitor 303 and sampling capacitor 306 may have the same capacitance value. Switches 304-305 may be connected in series between matching capacitor 303 and sampling capacitor 306. A common mode voltage (VCM) may be connected to a node between switches 304-305. In an embodiment, switches 301-302 may be connected in parallel between VCM and matching capacitor 303. Switch 307 may be connected in series with input voltage (VINP) 321 and sampling capacitor 306, with switch 307 being disposed in between VINP 321 and sampling capacitor 306. Switch 308 may be connected in series with a reference voltage through voltage DAC 322 and sampling capacitor 306, with switch 308 being disposed in between VREF 322 and sampling capacitor 306.

In an embodiment, switches 312-313 may be connected in series between capacitor 310 and capacitor 311, with a VCM being connected to a node between switch 312 and switch 313. Similarly, switches 317-318 may be connected in series between capacitor 315 and capacitor 316, with a VCM being connected to a node between switch 317 and switch 318.

Still referring to FIG. 3A, during a sampling phase, switches 301, 304-305, 307, 312-313 and 317-318 may be turned on (closed) and switches 302 and 308 may be turned off (open) to sample VINP 321 via sampling capacitor 306. In the sampling phase, the voltage across sampling capacitor 306 may be equal to (VCM-VINP). Furthermore, when VINP is getting sampled, the same sampling phase may be used for auto-zero of the comparators 309, 314 and 319. The charge lost on the auto-zero capacitors (e.g., capacitors 310, 311, 315, 318) can also get replenished or offset of comparator incrementally stored in the auto-zero capacitor at every sampling cycle. This incremental auto zeroing of the offset voltage would eliminate the need of a separate AZ phase, thereby avoiding the blind zone for the comparator.

Referring now to FIG. 3B, during a resolve phase, switches 301, 304-305, 307, 312-313 and 317-318 may be turned off (open) and switches 302 and 308 may be turned on (closed). In this phase, the voltages at input terminals 331-332 may be used for a comparison. In some embodiments, the voltage at input terminal 331 (VN) and the voltage at input terminal 332 (VP) may be computed as follows:

$${V}_{P} = ( VCM - VINP + VREF )$$

$${V}_{N} = VCM$$

FIG. 3C is a timing diagram illustrating a clock signal and comparator output signals associated with the comparator circuit of FIGS. 3A-3B. In FIG. 3C, clock signal 380, for example, may be used to control the switches 301-302, 304-305, 307-308, 312-313, 317-318. As shown, clock signal 380 may include a multiplicity of sample and auto-zero phases 350A-C (e.g., during low states) and a multiplicity of resolve phases 351A-C (e.g., during high states). The phase duration 370 of a sample and auto-zero phase and the phase duration 371 of a resolve phase may each be in a range of nanoseconds (ns), though the embodiments of the disclosure are not limited to this example. In FIG. 3C, complementary comparator output signals 390 may be produced at output terminal 320. The output signals 390 may include a multiplicity of valid data regions 360A-C.

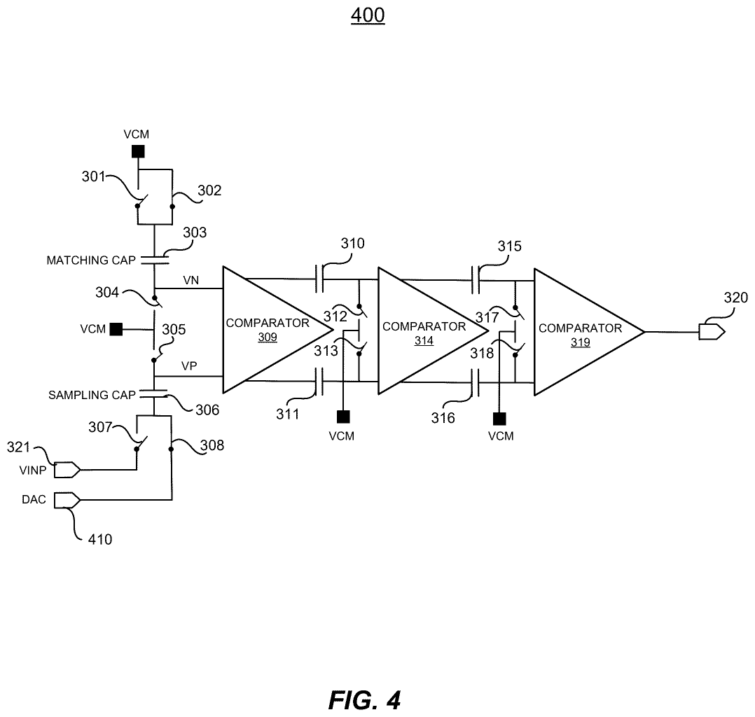

FIG. 4 is a schematic diagram illustrating an incremental auto-zero high-speed comparator circuit with DAC as reference according to an embodiment. In FIG. 4, comparator circuit 400 is similar to the comparator circuit 300 of FIG. 3B. Accordingly, for brevity's sake, the common components between comparator circuit 400 and comparator circuit 300 (e.g., comparators 309, 314, 319, switches 301-302, 304-305, 307-308, 312-313, 317-318, matching capacitor 303, sampling capacitor 306, and capacitors 310-311, 315-316) will not be described again herein.

As shown in FIG. 4, an output of DAC 410 may be used as a reference instead of VREF 322 (shown in FIG. 3B for example). In this embodiment, the DAC output is superimposed over the same (small) sampling capacitor 306 in the resolve phase. In addition, the architecture of comparator circuit 400 does not have voltage division with respect to the sampling capacitor 306, and thus, there is no additional gain error and a significant reduction of the sampling capacitor can be achieved. This architecture also allows the DAC 410 to be lightly loaded by the parasitic capacitance of the bottom plate of the sampling capacitor 306, which leads to a faster DAC transient response.

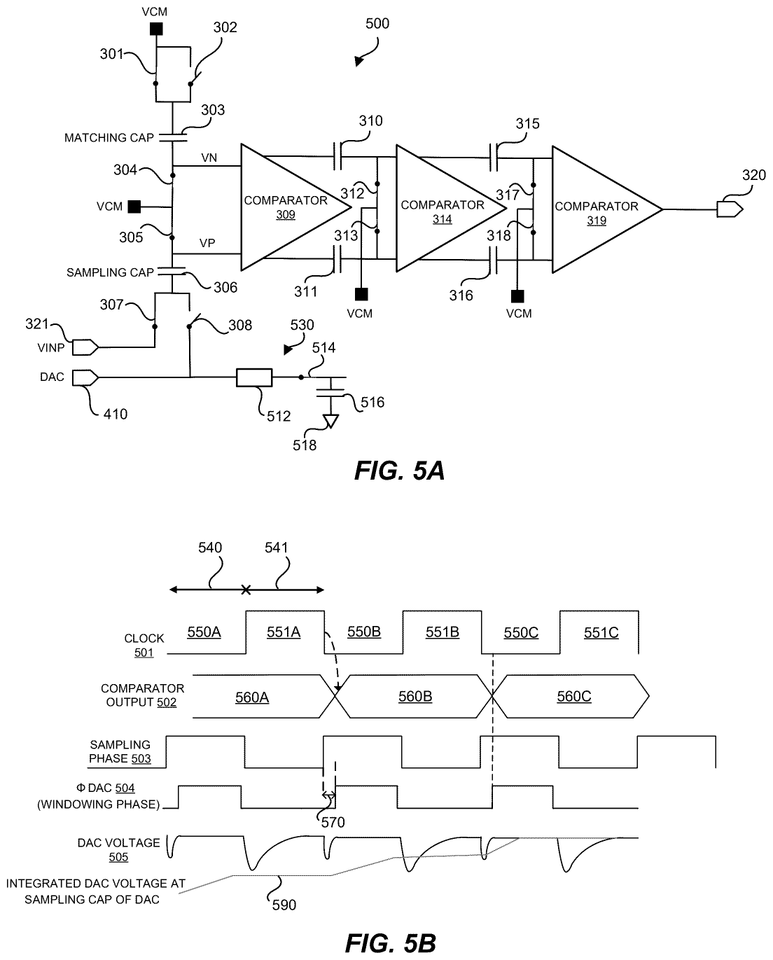

FIG. 5A is a schematic diagram illustrating an incremental auto-zero high-speed comparator circuit with reference voltage observability according to an embodiment. In FIG. 5A, comparator circuit 500 is similar to the comparator circuit 400 of FIG. 4. Accordingly, for brevity's sake, the common components between comparator circuit 500 and comparator circuit 400 (e.g., comparators 309, 314, 319, switches 301-302, 304-305, 307-308, 312-313, 317-318, matching capacitor 303, sampling capacitor 306, capacitors 310-311, 315-316, and DAC 410) will not be described again herein.

As shown in FIG. 5A, in addition to the components shown in comparator circuit 400, comparator circuit 500 may also include a windowed sampling mechanism 530 of a DAC voltage that includes a resistor 512, a switch (or switching device) 514 and a DAC sampling capacitor 516 connected in series between DAC 410 and GND 518. In the sampling phase, switch 514 may also be turned on (closed) to sample the DAC 410, using DAC sampling capacitor 516, for DAC observability. This embodiment allows the use of a separate windowing phase (φDAC) to control switch 514, which may have a delayed rising edge (phase delay) as compared to the sampling phase, when the DAC 410 is sampled. Moreover, a dedicated φDAC phase enables the incremental charging of the DAC sampling capacitor 516 when the DAC 410 is in a settle stage, thereby avoiding overshoot/undershoot error integration.

FIG. 5B is a timing diagram illustrating signals associated with the comparator circuit 500. In FIG. 5B, an incremental auto-zero concept is shown, where a DAC offset is stored in an auto-zero capacitor incrementally in successive auto-zero phases, so that after some clock cycles, a significant portion of the offset of the comparator is nullified. As shown, a clock signal 501 may be used to control the switches 301-302, 304-305, 307-308, 312-313, 317-318, 514. The clock signal 501 may include a multiplicity of sample and auto-zero phases 550A-C (e.g., during low states) and a multiplicity of resolve phases 551A-C (e.g., during high states). The phase duration 540 of a sample and auto-zero phase and the phase duration 541 of a resolve phase may each be in a range of nanoseconds, though the embodiments of the disclosure are not limited to this example. In FIG. 5B, complementary comparator output signals 502 may be produced at output terminal 320. The output signals 502 may include a multiplicity of valid data regions 560A-C.

As further illustrated in FIG. 5B, sampling phase 503 and windowing phase (§ DAC) 504 may have a delayed rising edge time 570 to allow the DAC (e.g., DAC 410) to settle prior to sampling. The sampled DAC voltages are shown in DAC voltage signal 505, and voltage signal 590 shows the integrated (or superimposed) DAC voltage at the sampling capacitor of the DAC (e.g., sampling capacitor 516).

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112 (f) or 35 U.S.C. 112, sixth paragraph, for that unit/circuit/component.

In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A comparator circuit, comprising:
a matching capacitor in series with a first switching device and a second switching device, wherein the first and second switching devices are in parallel between the matching capacitor and a reference voltage;
a sampling capacitor in series with a third switching device and a fourth switching device, wherein the third switching device is in series between the sampling capacitor and a digital-to-analog converter (DAC), and the fourth switching device is in series between the sampling capacitor and an input voltage;
a comparator having an inverting input terminal and a non-inverting input terminal, wherein the inverting input terminal is capacitively coupled to the matching capacitor and the non-inverting input terminal is capacitively coupled to the sampling capacitor; and
a fifth switching device and a sixth switching device in series between the matching capacitor and the sampling capacitor.

2. The comparator circuit of claim 1, wherein the reference voltage is connected to a node between the fifth and sixth switching devices.

3. The comparator circuit of claim 1, wherein during a sampling phase, the second, fourth, fifth, and sixth switching devices are closed and the first and third switching devices are open, to auto-zero an offset voltage of the comparator and sample the input voltage.

4. The comparator circuit of claim 1, wherein during a resolve phase, the second, fourth, fifth, and sixth switching devices are open and the first and third switching devices are closed, to charge the sampling capacitor via the DAC.

5. The comparator circuit of claim 1, further comprising the first, second, third and fourth switching devices and the DAC, wherein the first, second, third, fourth, fifth and sixth switching devices are selectively open and closed in response to a phase of a clock signal.

6. A comparator circuit, comprising:
a plurality of cascaded comparator amplifiers;
a matching capacitor in series with a first switching device and a second switching device, wherein the first and second switching devices are in parallel between the matching capacitor and a common mode voltage; and
a sampling capacitor in series with a third switching device and a fourth switching device, wherein the third switching device is in series between the sampling capacitor and an input voltage, and the fourth switching device is in series between the sampling capacitor and a reference voltage;
wherein a first comparator among the plurality of cascaded comparator amplifiers includes an inverting input terminal and a non-inverting input terminal, wherein the inverting input terminal is capacitively coupled to the matching capacitor and the non-inverting input terminal is capacitively coupled to the sampling capacitor.

7. The comparator circuit of claim 6, further comprising:
the first, second, third, and fourth switching devices;
a fifth switching device and a sixth switching device in series between the matching capacitor and the sampling capacitor.

8. The comparator circuit of claim 7, wherein:
the comparator circuit further comprises a first capacitor, a second capacitor, a third capacitor, and a fourth capacitor;
output terminals of the first capacitor are capacitively coupled to input terminals of a second capacitor among the plurality of cascaded comparator amplifiers via the first and second capacitors, respectively;
output terminals of the second capacitor are capacitively coupled to input terminals of a third capacitor among the plurality of cascaded comparator amplifiers via the third and fourth capacitors, respectively.

9. The comparator circuit of claim 8, further comprising:
a seventh switching device and an eighth switching device in series between the first and second capacitors; and
a ninth switching device and a tenth switching device in series between the third and fourth capacitors.

10. The comparator circuit of claim 9, wherein the common mode voltage is connected to a node between the fifth and sixth switching devices, a node between the seventh and eighth switching devices, and a node between the ninth and tenth switching devices.

11. The comparator circuit of claim 10, wherein during a first phase of a clock cycle, the first, third, fifth, sixth, seventh, eighth, ninth and tenth switching devices are closed and the second and fourth switching devices are open, to auto-zero offset voltages of the first, second and third comparators and sample the input voltage.

12. The comparator circuit of claim 11, wherein during a second phase of the clock cycle, the first, third, fifth, sixth, seventh, eighth, ninth and tenth switching devices are open and the second and fourth switching devices are closed, charge the sampling capacitor via the reference voltage.

13. A comparator circuit, comprising:
a plurality of cascaded comparator amplifiers;
a matching capacitor in series with a first switching device and a second switching device, wherein the first and second switching devices are in parallel between the matching capacitor and a common mode voltage; and
a sampling capacitor in series with a third switching device and a fourth switching device, wherein the third switching device is in series between the sampling capacitor and an input voltage, and the fourth switching device is in series between the sampling capacitor and a digital-to-analog converter (DAC);
wherein a first comparator among the plurality of cascaded comparator amplifiers includes an inverting input terminal and a non-inverting input terminal, wherein the inverting input terminal is capacitively coupled to the matching capacitor and the non-inverting input terminal is capacitively coupled to the sampling capacitor.

14. The comparator circuit of claim 13, further comprising:
the first, second, third, and fourth switching devices;
a fifth switching device and a sixth switching device in series between the matching capacitor and the sampling capacitor.

15. The comparator circuit of claim 14, wherein:
the comparator circuit further comprises a first capacitor, a second capacitor, a third capacitor, and a fourth capacitor;
output terminals of the first capacitor are capacitively coupled to input terminals of a second capacitor among the plurality of cascaded comparator amplifiers via the first and second capacitors, respectively;
output terminals of the second capacitor are capacitively coupled to input terminals of a third capacitor among the plurality of cascaded comparator amplifiers via the third and fourth capacitors, respectively.

16. The comparator circuit of claim 15, further comprising:
a seventh switching device and an eighth switching device in series between the first and second capacitors; and
a ninth switching device and a tenth switching device in series between the third and fourth capacitors.

17. The comparator circuit of claim 16, wherein the common mode voltage is connected to a node between the fifth and sixth switching devices, a node between the seventh and eighth switching devices, and a node between the ninth and tenth switching devices.

18. The comparator circuit of claim 17, further comprising:
a resistor, a switching device, and a DAC sampling capacitor in series between the DAC and a ground.

19. The comparator circuit of claim 18, wherein during a sampling phase of a clock cycle, the first, third, fifth, sixth, seventh, eighth, ninth and tenth switching devices are closed and the second and fourth switching devices are open, to auto-zero offset voltages of the first, second and third comparators and sample the input voltage.

20. The comparator circuit of claim 19, wherein during a dedicated windowing phase of the clock cycle, the switching device is closed to sample the DAC via the DAC sampling capacitor, wherein the dedicated windowing phase has a phase delay with respect to the sampling phase.
